(19) United States
(12) Patent Application Publication
(10) Pub. No.: US 2010/0255429 A1
(43) Pub. Date: Oct. 7, 2010

(54) FINE PATTERN FORMING METHOD AND COAT FILM FORMING MATERIAL

(75) Inventors: Kiyoshi Ishikawa, Kanagawa (JP); Jun Koshiyama, Kanagawa (JP); Kazumasa Wakiya, Kanagawa (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 12/671,805

(22) PCT Filed: Jul. 3, 2008
(86) PCT No.: PCT/JP2008/062042

§ 371 Date: Feb. 2, 2010

(30) Foreign Application Priority Data
Aug. 10, 2007 (JP) 2007-208777

(51) Int. Cl. G03F 7/20

(52) U.S. Cl. 430/324

(57) ABSTRACT

Provided are a fine pattern forming method for forming a fine resin pattern having an excellent shape on a supporting body, and a coat film forming material used in the fine pattern forming method. A photosensitive resin composition is applied on the supporting body, selectively exposed and developed to form a first resin pattern. On the surface of the first resin pattern, a coat film composed of a water-soluble resin film is formed to form a coat pattern, then, on the supporting body whereupon the coat pattern is formed, a resin composition containing a photo-acid generating agent is applied, and the entire surface is exposed. Then, the work is cleaned by a solvent, and a second resin pattern wherein a resin film is formed on the surface of the coat pattern is formed. The coat film is formed by using the coat film forming material composed of an aqueous solution containing a water soluble resin and a water soluble cross-linking agent.

### TECHNICAL FIELD

The present invention relates to a method for forming a fine pattern in which a fine resin pattern is formed on a support, and a material for forming a coat film used in the method for forming a fine pattern.

### BACKGROUND ART

In the production of electronic components such as semiconductor devices and liquid crystal devices, lithographic techniques have been used when a support is subjected to an etching treatment, etc. In the lithographic technique, a coat film (resist layer) is formed on a substrate using a resist material responsive to actinic radiation, then the resist layer is selectively irradiated with the actinic radiation, and thereafter a developing treatment is performed to selectively dissolve and remove the resist layer so as to form a resin pattern (resist pattern) on the support. Then, a pattern is formed on the support by carrying out an etching process with this resist pattern as a protective layer (mask pattern).

With a recent growing tendency to highly integrate and miniaturize semiconductor devices, micro-fabrication in the formation of these resist patterns has also advanced. In addition, as the actinic ray for use in forming the resist pattern, short wavelength ray such as KrF excimer laser beams, ArF excimer laser beams, F₂ excimer laser beams, EUV (extreme-ultraviolet ray), VUV (vacuum ultraviolet ray), EB (electron beam), X-ray and soft X-ray are utilized. Therefore, research and development of resist materials as a series of materials having physical properties corresponding to these actinic radiations have been performed.

In addition to attempt to achieve micro-fabrication in view of the improvements of such resist materials, research and development of techniques have been performed in order for the pattern micro-fabrication to exceed the resolution limit of conventional resist materials also in view of pattern formation methods.

For example, Patent Document 1 discloses a method for forming a fine pattern, the method including: covering the surface of a resist pattern including an acid generator by a material containing a substance that is crosslinkable in the presence of an acid; subjecting to a heat or exposure treatment to generate an acid in the resist pattern; and forming a crosslinked layer yielded on the boundary surface as a coat layer of the resist pattern to result in thickening of the resist pattern.

Furthermore, in Patent Document 2, a method is disclosed for forming a fine pattern by forming a resist pattern on a support, followed by heat-treatment thereof carried out to deform the cross-sectional shape of the resist pattern. Similarly, in Patent Document 3, a method is disclosed for forming a fine pattern by forming a resist pattern, followed by heating to approximately the softening temperature of the resist, so as to alter the pattern dimension by way of fluidization of the resist layer.

In addition, as a further developed method based on the methods described in Patent Documents 2 and 3, for example, Patent Document 4 discloses a method for forming a fine pattern, the method including: forming a resin film for preventing excessive flow of a resist layer on a support on which the resist pattern is formed; subjecting to a heat treatment to allow the resist layer to be fluidized, thereby altering the pattern dimension; and thereafter removing the resin film.

Patent Document 1: Japanese Unexamined Patent Application No. H10-73927

Patent Document 2: Japanese Unexamined Patent Application No. H1-307228

Patent Document 3: Japanese Unexamined Patent Application No. H4-364021

Patent Document 4: Japanese Unexamined Patent Application No. H7-45510

### DISCLOSURE OF THE INVENTION

### Problems to be Solved by the Invention

However, although the method disclosed in Patent Document 1 is comparatively favorable in pattern configuration, there is a problem of a small micro-fabrication size due to formation of a coat layer.

Moreover, according to the methods disclosed in Patent Documents 2 and 3, it is difficult to control the micro-fabrication size by the thermal flow, and there is a problem of difficulty in obtaining a favorable pattern configuration after the micro-fabrication process.

Furthermore, according to the method disclosed in Patent Document 4, it is difficult to obtain a favorable pattern configuration after the micro-fabrication process, and there is a problem of difficulty in suppressing variation of the micro-fabrication size of the resist pattern depending on variation of the heating temperature.

The present invention was made in view of the foregoing problems, and an object of the invention is to provide a method for forming a fine pattern in which a resin pattern having a fine and favorable configuration is formed on a support, and a material for forming a coat film for use in the method for forming a fine pattern.

### Means for Solving the Problems

The present inventors have thoroughly investigated to attain the object described above, and as a result have found that the problems described above can be solved by way of forming a water soluble resin film on a resin pattern, and thereafter forming a further resin film, thereby completing the present invention. Specifically, the present invention provides the following.

A first aspect of the present invention provides a method for forming a fine pattern, the method including the steps of: forming a first resin pattern by applying a photosensitive resin composition on a support, followed by selectively exposing, and then developing; forming a coat pattern by forming a coat film constituted with a water soluble resin film on the surface of the first resin pattern; and forming a second resin pattern constituted with a resin film formed on the surface of the coat pattern, by applying a resin composition containing a photoacid generator on the support having the coat pattern formed thereon, followed by exposing the entire face, and then washing with a solvent.

A second aspect of the present invention provides a material for forming a coat film, in which the material is constituted with an aqueous solution including a water soluble resin and a water soluble crosslinking agent, and in which the material is used for forming the coat film in the method for forming a fine pattern of the present invention.

### EFFECTS OF THE INVENTION

According to the present invention, a resin pattern having a fine and favorable configuration can be formed on a support.

### BRIEF DESCRIPTION OF THE DRAWINGS

FIGS. 1A-1E show a schematic process chart for illustrating a preferred embodiment of the method for forming a fine pattern of the present invention.

### EXPLANATION OF REFERENCE NUMERALS

1 support,
2 photosensitive resin layer,
3 first resin pattern,
4 coat film,
5 coat pattern,
6 resin layer,
7 resin film,
8 second resin pattern

### PREFERRED MODE FOR CARRYING OUT THE INVENTION

### Method for Forming Micropattern

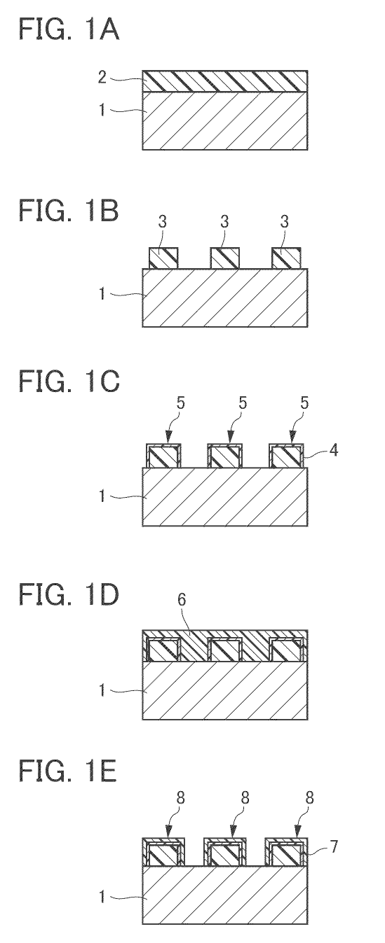

The method for forming a fine pattern of the present invention includes the steps of: forming a first resin pattern by applying a photosensitive resin composition on a support, followed by selectively exposing, and then developing (hereinafter, referred to as patterning step (1)); forming a coat pattern by forming a coat film constituted with a water soluble resin film on the surface of the first resin pattern (hereinafter, referred to as coating step); and forming a second resin pattern constituted with a resin film formed on the surface of the coat pattern, by applying a resin composition containing a photoacid generator on the support having the coat pattern formed thereon, followed by exposing the entire face, and then washing with a solvent (hereinafter, referred to as patterning step (2)). Hereinbelow, a preferred embodiment of the method for forming a micropattern of the present invention is described with reference to FIGS. 1A-1E.

### Patterning Step (1)

In the patterning step (1), as shown in FIG. 1A, a photosensitive resin composition is first applied on support 1 to form photosensitive resin layer 2. Next, as shown in FIG. 1B the photosensitive resin layer 2 is selectively exposed and developed to form first resin patterns 3.

### Support

There are no particular limitations as the support 1, and conventionally known materials can be used; for example, a substrate for electronic components, a substrate for electronic components on which a predetermined wiring pattern is formed, and the like can be exemplified. More specifically, examples of the substrate include silicon wafers, substrates made of a metal such as copper, chromium, iron or aluminum, glass substrates, and the like. As the material of the wiring pattern, copper, aluminum, nickel, gold or the like is available.

Also, as the support 1, the substrate as described above on which an antireflection film or an insulating film between layers is provided may be employed.

### Photosensitive Resin Composition

The photosensitive resin composition applied on the support 1 is not particularly limited, and any negative, positive, chemically amplified, or non-chemically amplified photosensitive resin compositions that have been conventionally used for semiconductor devices, liquid crystal devices, color filters, etc can be used. Among them, chemically amplified photosensitive resin compositions are preferred.

As the chemically amplified photosensitive resin composition, those prepared by dissolving a base material component (A) having an alkaline solubility that will be altered by the action of an acid (hereinafter, referred to as component (A)), and a photoacid generator component (B) that will generate an acid upon exposure (hereinafter, referred to as component (B)) in an organic solvent (S) (hereinafter, referred to as component (S)) are generally employed.

The term “base material component” herein means an organic compound having a film forming ability, and preferably, an organic compound having a molecular weight of no lower than 500 may be used. The organic compound having a molecular weight of no less than 500 improves film forming ability, and is likely to enable formation of a nano-scale pattern.

The organic compound having a molecular weight of no less than 500 is generally classified into organic compounds having a low molecular weight of no less than 500 and no greater than 2,000 (hereinafter, referred to as low-molecular compound), and a resin having a high molecular weight of greater than 2,000 (polymer). As the low-molecular compound, a nonpolymer is generally used.

The component (A) may be: a low-molecular compound having an alkaline solubility that will be altered by the action of an acid; a resin having an alkaline solubility that will be altered by the action of an acid; or any mixture of the same.

When the chemically amplified photosensitive resin composition is of a negative type, a base material component having an alkaline solubility that decreases by the action of an acid is used as the component (A), and a crosslinking agent is further blended in the negative photosensitive resin composition. In such a negative photosensitive resin composition, when an acid is generated from the component (B) upon exposure, a crosslinking reaction occurs between the component (A) and the crosslinking agent by the action of the acid, whereby the component (A) is altered from alkali-soluble to alkali-insoluble. Thus, when a photosensitive resin layer obtained by applying the negative photosensitive resin composition on a support is selectively exposed in forming a resin pattern, the exposed part is altered to become alkali-insoluble, whereas the unexposed part remains unchanged as alkali-soluble, thereby enabling development with an alkali.

As the component (A) of the negative photosensitive resin composition, an alkali-soluble resin is generally used. A resin having a unit derived from at least one selected from an (α-hydroxyalkyl)acrylic acid, and a lower alkyl ester of an (α-hydroxyalkyl)acrylic acid is preferred as the alkali-soluble resin since a favorable resin pattern with less swelling can be formed. The (α-hydroxyalkyl)acrylic acid refers to one or both of: acrylic acid having a hydrogen atom bound to a carbon atom at the α-position to which a carboxy group is bound, and α-hydroxyalkyl acrylic acid having a hydroxyalkyl group (preferably a hydroxyalkyl group having 1 to 5 carbon atoms) bound to the carbon atom at the α-position.

As the crosslinking agent, for example, an amino based crosslinking agent such as glycoluril having a methylol group or an alkoxymethyl group is preferably used, since a favorable resin pattern with less swelling can be formed. The amount of the crosslinking agent to be blended is preferably 1 to 50 parts by mass based on 100 parts by mass of the alkali-soluble resin.

When the chemically amplified photosensitive resin composition is of a positive type, a base material component having an acid-dissociable, dissolution-inhibiting group, and having an alkaline solubility that increases by the action of an acid may be used as the component (A). Such a positive photosensitive resin composition is alkali-insoluble prior to the exposure, and when an acid is generated from the component (B) upon exposure in forming the resin pattern, the component (A) is altered to be alkali-soluble because the acid-dissociable, dissolution-inhibiting group is dissociated by the action of the acid. Therefore, when a photosensitive resin layer obtained by applying the positive photosensitive resin composition on a support is selectively exposed in forming a resin pattern, the exposed part is altered to become alkali-soluble, whereas the unexposed part remains unchanged as alkali-insoluble, thereby enabling development with an alkali.

As the component (A) of the positive photosensitive resin composition, a resin having an acid-dissociable, dissolution-inhibiting group is generally used. A novolak resin, a hydroxystyrene based resin, an (α-lower alkyl)acrylic ester resin, a copolymer containing a constitutional unit derived from hydroxystyrene and a constitutional unit derived from an (α-lower alkyl)acrylic ester, and the like, which all have an acid-dissociable, dissolution-inhibiting group, are preferred as this resin. The (α-lower alkyl)acrylic acid refers to one or both of: acrylic acid having a hydrogen atom bound to a carbon atom at the α-position to which a carboxy group is bound, and α-lower alkyl acrylic acid having a lower alkyl group (preferably a lower alkyl group having 1 to 5 carbon atoms) bound to the carbon atom at the α-position.

The component (B) of the chemically amplified photosensitive resin composition may be appropriately selected for use from among conventionally known photoacid generators. As such a photoacid generator, onium salt based photoacid generators such as iodonium salts and sulfonium salts, oxime sulfonate based photoacid generators, diazomethane based photoacid generators such as bisalkyl- or bisarylsulfonyl diazomethanes and poly (bissulfonyl)diazomethanes, nitrobenzyl sulfonate based photoacid generators, iminosulfonate based photoacid generators, disulfone based photoacid generators, and the like have been conventionally known.

Specific examples of the onium salt based photoacid generator include diphenyliodonium trifluoromethane sulfonate, (4-methoxyphenyl) phenyliodonium trifluoromethane sulfonate, bis(p-tert-butylphenyl) iodonium trifluoromethane sulfonate, triphenylsulfonium trifluoromethane sulfonate, (4-methoxyphenyl) diphenylsulfonium trifluoromethane sulfonate, (4-methylphenyl) diphenylsulfonium nonafluorobutane sulfonate, (p-tert-butylphenyl) diphenylsulfonium trifluoromethane sulfonate, diphenyliodonium nonafluorobutane sulfonate, bis(p-tert-butylphenyl) iodonium nonafluorobutane sulfonate, triphenylsulfonium nonafluorobutane sulfonate, and the like. Among these, onium salts in which a fluorinated alkylsulfonic acid ion is included as an anion are preferred.

Specific examples of the oximesulfonate based photoacid generator include α-(methylsulfonyloxyimino)-phenylacetonitrile, α-(methylsulfonyloxyimino)-p-methoxyphenylacetonitrile, α-(trifluoromethylsulfonyloxyimino)-phenylacetonitrile, α-(trifluoromethylsulfonyloxyimino)-p-methoxyphenylacetonitrile, α-(ethylsulfonyloxyimino)-p-methoxyphenylacetonitrile, α-(propylsulfonyloxyimino)-p-methylphenylacetonitrile, α-(methylsulfonyloxyimino)-p-bromophenylacetonitrile, and the like. Among these, α-(methylsulfonyloxyimino)-p-methoxyphenylacetonitrile is preferred.

Specific examples of the diazomethane based photoacid generator include bis(isopropylsulfonyl)diazomethane, bis(p-toluenesulfonyl) diazomethane, bis(1,1-dimethylethylsulfonyl)diazomethane, bis(cyclohexylsulfonyl)diazomethane, bis(2,4-dimethylphenylsulfonyl)diazomethane, and the like.

As the component (B), a single photoacid generator may be used alone, or two or more acid generators may be used in combination.

The amount of the component (B) used is 1 to 20 parts by mass, and preferably 2 to 10 parts by mass based on 100 parts by mass of the component (A). By including the component (B) in an amount not below the above lower limit, sufficient pattern formation is achieved. Whereas, when the amount does not exceed the upper limit of the above range, homogeneity of the solution is likely to be accomplished, whereby favorable storage stability is achieved.

As the component (S) of the chemically amplified photosensitive resin composition, any one may be appropriately selected for use from among conventionally known organic solvents.

Specific examples of the component (S) include lactones such as γ-butyrolactone; ketones such as acetone, methyl ethyl ketone, cyclohexanone, methyl isoamyl ketone and 2-heptanone; polyhydric alcohols and derivatives thereof such as ethylene glycol, ethylene glycol monoacetate, diethylene glycol, diethylene glycol monoacetate, propylene glycol, propylene glycol monoacetate, propylene glycol monomethyl ether acetate (PGMEA) and dipropylene glycol, or monomethyl ether, monoethyl ether, monopropyl ether, monobutyl ether or monophenyl ether thereof; cyclic ethers such as dioxane; esters such as methyl lactate, ethyl lactate (EL), methyl acetate, ethyl acetate, butyl acetate, methyl pyruvate, ethyl pyruvate, methyl methoxypropionate and ethyl ethoxypropionate; and the like. Among these, PGMEA, EL, and propylene glycol monomethyl ether (PGME) are preferred. These organic solvents may be used alone, or in combination of two or more thereof.

The amount of the component (S) used is not particularly limited, but the component (S) may be used in an amount sufficient to provide a liquid having a density which enables the chemically amplified photosensitive resin composition to be applied on the support 1.

The chemically amplified photosensitive resin composition may further appropriately contain if desired, additives having miscibility, such as for example, an additional resin for improving the characteristics of the coat film, a surfactant for improving application abilities, a dissolution-preventing agent, a plasticizer, a stabilizer, a colorant, a halation inhibitor, and the like.

### Formation of First Resin Pattern

The photosensitive resin layer 2 can be formed by applying the photosensitive resin composition as described above on the support 1. The photosensitive resin composition can be applied by a conventionally known method using a spinner or the like.

Specifically, the photosensitive resin layer 2 can be formed by, for example: applying the photosensitive resin composition on the support 1 using a spinner or the like, and subjecting to a baking treatment (prebaking) under a temperature condition of 80 to 150° C. for 40 to 120 sec, and preferably 60 to 90 sec to volatilize the organic solvent.

The photosensitive resin layer 2 has a thickness of preferably 50 to 500 nm, and more preferably 50 to 450 nm. Providing the resin layer having a thickness within the above range leads to effects such as to enable formation of a resin pattern with a high resolution.

Exposure and development of the photosensitive resin layer 2 can be performed utilizing a conventionally known method. For example, the photosensitive resin layer 2 is selectively exposed through a mask having a predetermined pattern formed thereto (mask pattern), followed by subjecting to a baking treatment (PEB (post exposure baking)) under a temperature condition of 80 to 150° C. for 40 to 120 sec, and preferably 60 to 90 sec, and then alkali development is conducted with, for example, an aqueous tetramethyl ammonium hydroxide (TMAH) solution having a concentration of 0.1 to 10% by mass. Accordingly, when the photosensitive resin composition employed is of a negative type, the unexposed part is removed, whereas in the case of the positive type, the exposed part is removed to permit formation of the first resist pattern 3.

The wavelength used in the exposure is not particularly limited, and the exposure can be conducted using an actinic radiation such as a KrF excimer laser, an ArF excimer laser, an F₂ excimer laser, EUV, VUV, EB, an X-ray, and a soft X-ray.

The selective exposure of the photosensitive resin layer 2 in this step may be general exposure conducted in an inert gas such as nitrogen or air (dry exposure), or liquid immersion exposure.

In the liquid immersion exposure, exposure is conducted while allowing a solvent (liquid immersion medium) having a refractive index greater than that of the air to be filled in a part between the photosensitive resin layer 2 on the support 1 and the lens, which has been conventionally filled with an inert gas such as nitrogen or air. More specifically, the liquid immersion exposure can be performed by filling in between the photosensitive resin layer 2 obtained as described above and the lens positioned at the undermost of the exposure device with a solvent (liquid immersion medium) having a refractive index greater than that of air, and then exposing through a desired mask pattern in such a state (immersion exposure).

As the liquid immersion medium, a solvent having a refractive index greater than that of the air, and less than that of the photosensitive resin layer 2 is preferred. The refractive index of such a solvent is not particularly limited as long as it falls within the range as described above. Examples of the solvent having a refractive index greater than that of the air, and less than that of the photosensitive resin layer 2 include water, fluorocarbon inert liquids, silicon based solvents, hydrocarbon based solvents, and the like.

### Coating Step

In the coating step, as shown in FIG. 1C, coat films 4 constituted with a water soluble resin film are formed on the surface of the first resin patterns 3, respectively, to form coat patterns 5.

As the method for forming the coat film 4, a method in which a material for forming a coat film, which is constituted with an aqueous solution that contains a water soluble resin and a water soluble crosslinking agent, is preferably employed. Details of the material for forming a coat film will be described later.

When this material for forming a coat film is used, the coat film 4 can be formed by, for example, applying the material for forming a coat film on the surface of the first resin pattern 3 to form a coat film, and thereafter subjecting the coat film to a baking treatment.

Known methods can be employed as the method for applying the material for forming a coat film, such as for example: a method in which the support 1 having the first resin pattern 3 formed thereon is immersed in a material for forming a coat film (dip coating method); a method in which a material for forming a coat film is applied on the support 1 by a spin coating method; and the like. Alternatively, methods such as a layer-by-layer sequential adsorption method and the like also enable the formation.

In the coating step, the coat film is subjected to a baking treatment after applying the material for forming a coat film. This baking treatment forms the coat film 4 on the surface of the first resin pattern 3. When a chemically amplified photosensitive resin composition is used in forming the first resin pattern 3, this baking treatment leads to acceleration of diffusion of the acid from the first resin pattern 3, whereby a crosslinking reaction is caused at the interface of the first resin pattern 3 and the coat film, and thus a rigid coat film 4 can be formed.

In the baking treatment, the baking temperature is preferably 70 to 180° C., and more preferably 80 to 170° C. By baking at a temperature falling within this range, a rigid coat film 4 can be formed. Although the baking time period is not particularly limited, it is preferably 30 to 300 sec, and more preferably 60 to 180 sec, taking into consideration the effect achieved by the baking treatment, and the stability of the pattern configuration.

When a chemically amplified photosensitive resin composition is used in forming the first resin pattern 3, the surface of the support 1 is preferably washed with a cleaning liquid after applying the material for forming a coat film. Thus, even though the excess water soluble resin is adhered to the surface of the part where the first resin pattern 3 is not present (part without pattern) on the support 1, such a resin can be washed away by the cleaning liquid, or its concentration is extremely lowered. Meanwhile, since the water soluble resin on the surface of the first resin pattern 3 is crosslinked, it is left as is thereon. As a consequence, the water soluble resin film is sufficiently formed on the surface of the first resin pattern 3, while the water soluble resin film is scarcely or not formed on the surface of the part without the pattern on the support 1. Accordingly, a water soluble resin film (coat film 4) can be formed on the surface of the first resin pattern 3 with high coating selectivity.

Furthermore, the coat film 4 which is uniform and has a small film thickness can be provided by washing. More specifically, uncrosslinked excess water soluble resin on the first resin pattern 3 is eliminated by washing, while the water soluble resin more strongly bound to the pattern surface through crosslinking is uniformly left on the pattern surface. Therefore, a thin film of the water soluble resin at a nanometer level can be formed with a uniform film thickness and extremely high accuracy, and with high reproducibility.

The cleaning liquid is acceptable as long as it can dissolve and remove uncrosslinked water soluble resin and the like, and for example, similar ones exemplified as solvents for the material for forming a coat film described later can be used.

The washing can be carried out by a known method. Examples of the method include: a method in which the cleaning liquid is supplied by a spraying method on the surface of the coat film constituted with the material for forming a coat film, and thereafter the excess cleaning liquid is aspirated under a reduced pressure; a method of immersion and washing in the cleaning liquid; a method of spraying and washing; a method of washing with steam; a method in which the cleaning liquid is applied on the support with a spin coating method; and the like, and the spin coating method is preferred in particular. Washing conditions (washing time, amount of the cleaning liquid used, and the like) may be predetermined appropriately taking into consideration the washing method and the like. When the washing is carried out by, for example, a spin coating method, the conditions may be adjusted appropriately in the range of approximately 100 to 5,000 rpm for around 1 to 100 sec.

It is preferred that the washing be carried out before complete volatilization of the solvent in the coat film constituted with the material for forming a coat film. Complete or incomplete volatilization of the solvent can be confirmed by visual observation.

The coat film 4 has a thickness of preferably no less than 0.1 nm, more preferably 0.5 to 50 nm, and still more preferably 1 to 30 nm.

### Patterning Step (2)

In the patterning step (2), a resin composition containing a photoacid generator is first applied on the support 1 having coat patterns 5 formed thereon to form a resin layer 6 that covers the coat patterns 5, as shown in FIG. 1D. Next, as shown in FIG. 1E, the entire face of the resin layer 6 is exposed, and washed with a solvent to form a second resin pattern 8 having a resin film 7 formed on the surface of the coat pattern 5. Accordingly, a second resin pattern that is finer than the first resin pattern 3 formed in the patterning step (1) is formed on the support 1.

### Resin Composition

The resin composition to be applied on the support 1 having the coat patterns 5 formed thereon is not particularly limited as long as it contains a photoacid generator, and any resin composition can be used.

As such a resin composition, a mixture of a base material component and a photoacid generator component dissolved in an organic solvent may be used. The base material component may be exemplified by, e.g., a resin having an acid-dissociable, dissolution-inhibiting group described in regard to the patterning step (1), or a resin not having an acid-dissociable, dissolution-inhibiting group, and the like. Moreover, as the photoacid generator component and the organic solvent, the component (B) and the component (S) described in regard to the patterning step (1) may be used.

As such a resin composition, the photosensitive resin compositions described in regard to the patterning step (1) are preferred. In addition, the resin composition may also include the crosslinking agent described above.

When the resin composition is photosensitive, a similar chemically amplified photosensitive resin composition for use in the patterning step (1) may be used as the photosensitive resin composition. The chemically amplified photosensitive resin composition may be either of a negative or positive type, and a positive type is preferred.

### Formation of Second Resin Pattern

The resin layer 6 can be formed by applying the resin composition as described above on the support 1 having the coat patterns 5 formed thereon. The resin composition can be applied by a conventionally known method using a spinner or the like.

Specifically, the resin layer 6 can be formed by, for example: applying the resin composition on the support 1 having the coat patterns 5 formed thereon using a spinner or the like, and subjecting to a baking treatment (prebaking) under a temperature condition of 80 to 150° C. for 40 to 120 sec, and preferably 60 to 90 sec to volatilize the organic solvent.

The entire face of the resin layer 6 can be exposed by utilizing a conventionally known method. The wavelength used in the exposure is not particularly limited, and the exposure can be conducted using an actinic radiation such as a KrF excimer laser, an ArF excimer laser, an F₂ excimer laser, EUV, VUV, EB, an X-ray, and a soft X-ray. When an acid is generated from the photoacid generator component in the resin layer 6 upon exposure in this manner, the base material component in the resin layer 6 interacts with the coat film 4 due to the action of the acid, whereby the resin film 7 is formed on the surface of the coat pattern 5.

Thereafter, washing of the surface of the support 1 with a solvent removes the resin layer 6 except for the resin film 7, whereby a second resin pattern 8 having the resin film 7 formed on the surface of the coat pattern 5 is obtained.

The solvent for washing is acceptable as long as it can dissolve and remove the resin layer 6. For example, an aqueous tetramethyl ammonium hydroxide (TMAH) solution having a concentration of 0.1 to 10% by mass can be used.

The washing can be carried out by a known method. Examples of the method include: a method in which the solvent is supplied by a spraying method on the surface of the resin layer 6, and thereafter the excess solvent is aspirated under a reduced pressure; a method of immersion and washing in the solvent; a method of spraying and washing; a method of washing with steam; a method in which the solvent is applied on the support with a spin coating method; and the like, and the spin coating method is preferred in particular. Washing conditions (washing time, amount of the cleaning liquid used, and the like) may be predetermined appropriately taking into consideration the washing method and the like. When the washing is carried out by, for example, a spin coating method, the conditions may be adjusted appropriately in the range of approximately 100 to 5,000 rpm for around 1 to 100 sec.

The resin film 7 has a thickness of preferably no less than 100 nm, more preferably 100 to 1,000 nm, and still more preferably 120 to 500 nm.

The second resin pattern formed as described above can be used as a resist pattern for use in forming, for example, contact holes. According to the present invention, in particular, fine contact holes can be formed since the micro-fabrication of the holes having a small diameter is enabled.

### Material for Forming Coat Film

The material for forming a coat film of the present invention is constituted with an aqueous solution that contains a water soluble resin and a water soluble crosslinking agent, and is used for forming the coat film in the method for forming a fine pattern of the present invention.

### Water Soluble Resin

The water soluble resin is not particularly limited as long as it is a resin which can be dissolved in water at room temperature, and is preferably constituted to include at least one selected from an acrylic based resin, a vinyl based resin, a cellulose based resin and an amide based resin, in the present invention.

Examples of the acrylic based resin include polymers or copolymers constituted with a monomer such as acrylic acid, methyl acrylate, methacrylic acid, methyl methacrylate, N,N-dimethylacrylamide, N,N-dimethylaminopropylmethacrylamide, N,N-dimethylaminopropylacrylamide, N-methylacrylamide, diacetoneacrylamide, N,N-dimethylaminoethyl methacrylate, N,N-diethylaminoethyl methacrylate, N,N-dimethylaminoethyl acrylate, acryloyl morpholine, and the like.

Examples of the vinyl based resin include polymers or copolymers constituted with a monomer such as N-vinylpyrrolidone, vinylimidazolidinone, vinyl acetate or the like.

Examples of the cellulose based resin include hydroxypropyl methylcellulose phthalate, hydroxypropyl methylcellulose acetate phthalate, hydroxypropyl methylcellulose hexahydrophthalate, hydroxypropyl methylcellulose acetate succinate, hydroxypropyl methylcellulose, hydroxypropyl cellulose, hydroxyethyl cellulose, cellulose acetate hexahydrophthalate, carboxymethyl cellulose, ethyl cellulose, methyl cellulose, and the like.

Furthermore, among amide based resins, those which are soluble in water can be also used.

Of these examples, vinyl based resins are preferred, and particularly polyvinylpyrrolidone and polyvinyl alcohol are preferred.

These water soluble resins may be used alone, or two or more thereof may be used as a mixture.

In order to provide the coat film having a film thickness that is necessary and sufficient for use, the amount of the water soluble resin included is preferably about 1 to 99% by mass, more preferably about 40 to 99% by mass, and still more preferably about 65 to 99% by mass of the solid content of the material for forming a coat film.

### Water Soluble Crosslinking Agent

The water soluble crosslinking agent has at least one nitrogen atom in the structure thereof. As such a water soluble crosslinking agent, a nitrogen-containing compound having an amino group and/or imino group in which at least two hydrogen atoms are substituted with a hydroxyalkyl group and/or alkoxyalkyl group is preferably used. Examples of such nitrogen-containing compounds include melamine based derivatives, urea based derivatives, guanamine based derivatives, acetoguanamine based derivatives, benzoguanamine based derivatives and succinyl amide based derivatives in which the hydrogen atom of the amino group is substituted with a methylol group or an alkoxymethyl group or both of these, as well as glycoluril based derivatives and ethylene urea based derivatives in which the hydrogen atom of the imino group is substituted, and the like.

Among these nitrogen-containing compounds, at least one or more of: triazine based derivatives such as benzoguanamine based derivatives, guanamine based derivatives, and melamine based derivatives; glycoluril based derivatives; and urea based derivatives, which have an amino group or an imino group in which at least two hydrogen atoms are substituted with a methylol group or a (lower alkoxy)methyl group, or both of these, are preferred in view of the crosslinking reactivity.

The amount of the water soluble crosslinking agent included is preferably about 1 to 99% by mass, more preferably about 1 to 60% by mass, and still more preferably 1 to 35% by mass of the solid content of the material for forming a coat film.

### Solvent

The material for forming a coat film of the present invention is usually used in the form of an aqueous solution that contains the water soluble resin and the water soluble crosslinking agent. This material for forming a coat film is preferably used in the form of an aqueous solution having a concentration of 3 to 50% by mass, and more preferably used in the form of an aqueous solution having a concentration of 5 to 20% by mass. When the concentration is less than 3% by mass, failure in coating the resin pattern may result, while a concentration exceeding 50% by mass is not preferred since improvement of effects appropriately corresponding to the increased concentration cannot be found, and also in view of the handleability.

Furthermore, a mixed solvent including water and an alcoholic solvent may be also used as the solvent. Examples of the alcoholic solvent include methyl alcohol, ethyl alcohol, propyl alcohol, isopropyl alcohol, glycerin, ethylene glycol, propylene glycol, 1,2-butylene glycol, 1,3-butylene glycol, 2,3-butylene glycol, and the like. These alcoholic solvents may be used as a mixture with water in a proportion up to 30% by mass.

### Optional Component

An optional component may be blended into the material for forming a coat film as follows, in addition to the water soluble resin and the water soluble crosslinking agent.

### Surfactant

A surfactant, for example, may be blended into the material for forming a coat film. Although the surfactant is not particularly limited, characteristics such as high solubility in the aforementioned water soluble resin, and preclusion of development of suspension, and the like are required. Use of such a surfactant that complies with these characteristics can suppress generation of air bubble (microfoam), especially when applying the material for forming a coat film, thereby enabling prevention of defect generation reportedly related to the microfoam generation. In view of the foregoing aspects, one or more of an N-alkylpyrrolidone based surfactant, a quaternary ammonium salt based surfactant, a surfactant based on a phosphoric acid ester of polyoxyethylene, and a nonium based surfactant may be preferably used.

As the N-alkylpyrrolidone based surfactant, a compound represented by the following general formula (1) is preferred.

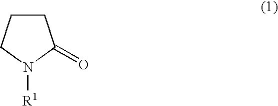

In the formula (1), R¹ represents an alkyl group having 6 or more carbon atoms.

Specific examples of such an N-alkylpyrrolidone based surfactant include N-hexyl-2-pyrrolidone, N-heptyl-2-pyrrolidone, N-octyl-2-pyrrolidone, N-nonyl-2-pyrrolidone, N-decyl-2-pyrrolidone, N-decyl-2-pyrrolidone, N-undecyl-2-pyrrolidone, N-dodecyl-2-pyrrolidone, N-tridecyl-2-pyrrolidone, N-tetradecyl-2-pyrrolidone, N-pentadecyl-2-pyrrolidone, N-hexadecyl-2-pyrrolidone, N-heptadecyl-2-pyrrolidone, N-octadecyl-2-pyrrolidone, and the like. Among these, N-octyl-2-pyrrolidone (“SURFADONE LP 100”; manufactured by ISP) is preferably used.

As the quaternary ammonium based surfactant, a compound represented by the following general formula (2) is preferred.

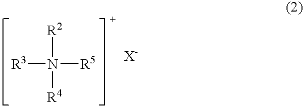

In the above general formula (2), R², R³, R⁴, R⁵ each independently represent an alkyl group or a hydroxyalkyl group (wherein, at least one of them represents an alkyl group or a hydroxyalkyl group having 6 or more carbon atoms), and X⁻ represents a hydroxide ion or a halogen ion.

Specifically, such quaternary ammonium surfactants include dodecyltrimethylammonium hydroxide, tridecyltrimethylammonium hydroxide, tetradecyltrimethylammonium hydroxide, pentadecyltrimethylammonium hydroxide, hexadecyltrimethylammonium hydroxide, heptadecyltrimethylammonium hydroxide, octadecyltrimethylammonium hydroxide, and the like. Among these, hexadecyltrimethylammonium hydroxide is preferably used.

As the aforementioned surfactant based on a phosphoric acid ester of polyoxyethylene, a compound represented by the following general formula (3) is preferred.

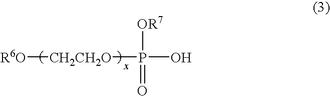

In the above general formula (3), R⁶ represents an alkyl group or an alkylallyl group having 1 to 10 carbon atoms; R⁷ represents a hydrogen atom or (CH₂CH₂O) R⁶ (wherein R⁶ is as defined above); and x represents an integer of 1 to 20.

Specifically, as such a surfactant based on a phosphoric acid ester of polyoxyethylene, commercially available products such as “Plysurf A212E” and “Plysurf A210G” (both manufactured by Dai-ichi Kogyo Seiyaku Co., Ltd.) can be preferably used.

The nonionic surfactant is preferably an alkyl etherified product of polyoxyalkylene, or an alkylamine oxide compound.

As the alkyl etherified product of polyoxyalkylene, a compound represented by the following general formula (4) or (5) is preferably used.

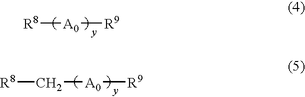

In the above general formulae (4) and (5), R⁸ and R⁹ represent a linear, branched or cyclic alkyl group, an alkyl group having a hydroxyl group, or an alkylphenyl group having 1 to 22 carbon atoms. A₀ represents an oxyalkylene group, and is preferably at least one selected from oxyethylene, oxypropylene, and oxybutylene groups. The symbol y represents an integer.

As the alkylamine oxide compound, a compound represented by the following general formula (6) or (7) is preferably used.

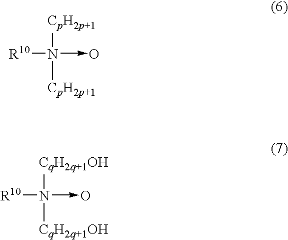

In the above general formulae (6) and (7), R¹⁰ represents an alkyl group or a hydroxyalkyl group having 8 to 20 carbon atoms which may be interrupted with an oxygen atom, and p and q represent an integer of 1 to 5.

Examples of the alkylamine oxide compound represented by the above general formulae (6) and (7) include octyldimethylamine oxide, dodecyldimethylamine oxide, decyldimethylamine oxide, lauryldimethylamine oxide, cetyldimethylamine oxide, stearyldimethylamine oxide, isohexyldiethylamine oxide, nonyldiethylamine oxide, lauryldiethylamine oxide, isopentadecylmethylethylamine oxide, stearylmethylpropylamine oxide, lauryldi(hydroxyethyl)amine oxide, cetyldiethanolamine oxide, stearyldi(hydroxyethyl)amine oxide, dodecyloxyethoxyethoxyethyldi(methyl)amine oxide, stearyloxyethyldi(methyl)amine oxide, and the like.

Among these surfactants, a nonium based surfactant is preferably used in light of reduction of defects, in particular.

The amount of the surfactant included is preferably about 0.1 to 10% by mass, and more preferably about 0.2 to 2% by mass of the solid content of the material for forming a coat film. When the amount does not fall within the above range, problems such as deterioration of the application abilities, or generation of defect which is believed to be significantly associated with bubble, which may be referred to as microfoam, that is generated during application may result.

### Water Soluble Fluorine Compound

A water soluble fluorine compound may be blended into the material for forming a coat film. Although the water soluble fluorine compound is not particularly limited, characteristics such as high solubility in the aforementioned water soluble resin, and preclusion of development of suspension, and the like are required. Use of a water soluble fluorine compound that complies with such characteristics can improve a leveling property (extent of spreading of the material for forming a coat film). Although this leveling property can be achieved by lowering of the contact angle by adding a surfactant, when the amount of addition of the surfactant is in excess, an improving ability for application at a certain level or higher cannot be achieved, but by adding in an excess amount, the bubble (microfoam) may be generated on the coat film depending on the application conditions, thereby leading to a problem of potentially causing defects. By blending this water soluble fluorine compound, the contact angle is lowered while suppressing such foaming, and thus leveling properties can be improved.

As the water soluble fluorine compound, fluoroalkyl alcohols, fluoroalkylcarboxylic acids and the like are preferably used. Examples of the fluoroalkyl alcohols include 2-fluoro-1-ethanol, 2,2-difluoro-1-ethanol, trifluoroethanol, tetrafluoropropanol, octafluoroamyl alcohol, and the like. Examples of the fluoroalkylcarboxylic acids include trifluoroacetic acid, and the like. However, the fluoroalkylcarboxylic acid is not limited to such exemplified compounds, and is acceptable as long as it is a fluorine compound having water solubility, and exhibits the effects described above. In particular, fluoroalkyl alcohols having 6 or less carbon atoms may be preferably used. Among these, in light of ready availability and the like, trifluoroethanol is particularly preferred.

The amount of the water soluble fluorine compound included is preferably about 0.1 to 30% by mass, and more preferably about 0.1 to 15% by mass of the solid content of the material for forming a coat film. When the amount of blending is below the above range, application abilities may be deteriorated. When the compound is included in an amount exceeding the aforementioned upper limit, improvement of the leveling properties to meet such an amount of blending cannot be expected.

### Amide Group-Containing Monomer

An amide group-containing monomer may be blended into the material for forming a coat film. Although the amide group-containing monomer is not particularly limited, characteristics such as high solubility in the aforementioned water soluble resin, and preclusion of development of suspension, and the like are required.

As the amide group-containing monomer, the amide compound represented by the following general formula (8) is preferably used.

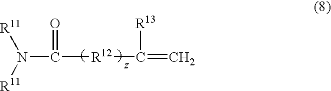

In the above general formula (8), R¹¹ represents a hydrogen atom, an alkyl group or a hydroxyalkyl group having 1 to 5 carbon atoms; R¹² represents an alkyl group having 1 to 5 carbon atoms; R¹³ represents a hydrogen atom or a methyl group; and z represents a number of 0 to 5. In the foregoing, the alkyl group, and the hydroxyalkyl group may be either linear, or branched.

In the above general formula (8), an amide group-containing monomer in which R¹¹ represents a hydrogen atom, a methyl group, or an ethyl group; and z represents 0 is more preferably used. Specific examples of the amide group-containing monomer include acrylamide, methacrylamide, N,N-dimethylacrylamide, N,N-dimethylmethacrylamide, N,N-diethylacrylamide, N,N-diethylmethacrylamide, N-methylacrylamide, N-methylmethacrylamide, N-ethylacrylamide, N-ethylmethacrylamide, and the like. Among these, acrylamide, and methacrylamide are particularly preferred.

The amount of the amide group-containing monomer included is preferably about 0.1 to 30% by mass, and more preferably about 1 to 15% by mass of the solid content of the material for forming a coat film. When the amount is less than 0.1% by mass, desired effects are hardly achieved. Meanwhile, even though the amount is beyond 30% by mass, an additional effect in response to the amount blended is not achieved.

Heterocyclic Compound Having at Least Oxygen Atom and/or Nitrogen Atom

A heterocyclic compound having at least an oxygen atom and/or nitrogen atom may be blended into the material for forming a coat film.

As the heterocyclic compound, at least one selected from a compound having an oxazolidine skeleton, a compound having an oxazoline skeleton, a compound having an oxazolidone skeleton, and a compound having an oxazolidinone skeleton is preferably used.

Examples of the compound having an oxazolidine skeleton include oxazoline represented by the following formula (9), as well as substituted products thereof.

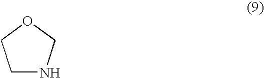

Examples of the substituted product include compounds having substitution of a hydrogen atom bound to the carbon atom or nitrogen atom of oxazoline represented by the above formula (9), with a substituted or unsubstituted lower alkyl group having 1 to 6 carbon atoms, a carboxyl group, a hydroxyl group, or a halogen atom. As the substituted lower alkyl group, a hydroxyalkyl group, a (lower alkoxy)alkyl group, and the like may be exemplified, but not limited thereto.

Examples of the compound having an oxazoline skeleton include 2-oxazoline represented by the following formula (10-1), 3-oxazoline represented by the following formula (10-2), 4-oxazoline represented by the following formula (10-3), as well as substituted products thereof.

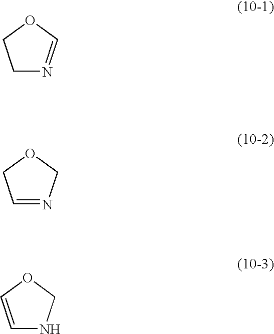

Examples of the substituted product include compounds having substitution of a hydrogen atom bound to the carbon atom or nitrogen atom of a compound having an oxazoline skeleton represented by the above formulae (10-1) to (10-3), with a substituted or unsubstituted lower alkyl group having 1 to 6 carbon atoms, a carboxyl group, a hydroxyl group, or a halogen atom. As the substituted lower alkyl group, a hydroxyalkyl group, a (lower alkoxy)alkyl group, and the like may be exemplified, but not limited thereto.

Among the compounds having an oxazoline skeleton, 2-methyl-2-oxazoline represented by the following formula (10-1-A) is preferably used.

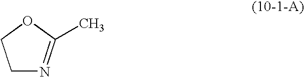

Examples of the compound having an oxazolidone skeleton include 5(4)-oxazolone represented by the following formula (11-1), 5(2)-oxazolone represented by the following formula (11-2), 4(5)-oxazolone represented by the following formula (11-3), 2(5)-oxazolone represented by the following formula (11-4), 2(3)-oxazolone represented by the following formula (11-5), as well as substituted products thereof.

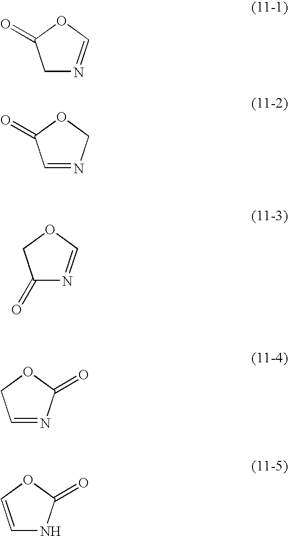

Examples of the substituted product include compounds having substitution of a hydrogen atom bound to the carbon atom or nitrogen atom of a compound having an oxazoline skeleton represented by the above formulae (11-1) to (11-5), with a substituted or unsubstituted lower alkyl group having 1 to 6 carbon atoms, a carboxyl group, a hydroxyl group, or a halogen atom. As the substituted lower alkyl group, a hydroxyalkyl group, a (lower alkoxy)alkyl group, and the like may be exemplified, but not limited thereto.

Examples of the compound having an oxazolidinone skeleton (or compound having a 2-oxazolidone skeleton) include oxazolidinone (or 2-oxazolidone) represented by the following formula (12), as well as substituted products thereof.

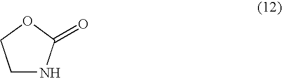

Examples of the substituted product include compounds having substitution of a hydrogen atom bound to the carbon atom or nitrogen atom of oxazolidinone (or 2-oxazolidone) represented by the above formula (12), with a substituted or unsubstituted lower alkyl group having 1 to 6 carbon atoms, a carboxyl group, a hydroxyl group, or a halogen group. As the substituted lower alkyl group, a hydroxyalkyl group, a (lower alkoxy)alkyl group, and the like may be exemplified, but not limited thereto.

Among the compounds having an oxazolidinone skeleton, 3-methyl-2-oxazolidone represented by the following formula (12-1) is preferably used.

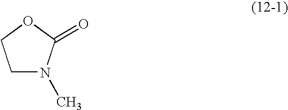

The amount of the heterocyclic compound having at least an oxygen atom and/or nitrogen atom blended is preferably 1 to 50% by mass, and more preferably 3 to 20% by mass based on the mass of the water soluble resin. When the amount is less than 1% by mass, desired effects are hardly achieved. Meanwhile, even though the amount is beyond 50% by mass, the effect is not improved to meet the amount of blending.

### Heterocyclic Compound Having Two or More Nitrogen Atoms in at Least the Same Ring

A heterocyclic compound having two or more nitrogen atoms in at least the same ring may be blended into the material for forming a coat film.

Examples of the heterocyclic compound having two or more nitrogen atoms in at least the same ring include pyrazole based compounds such as pyrazole, 3,5-dimethylpyrazole, 2-pyrazoline, 5-pyrazolone, 3-methyl-1-phenyl-5-pyrazolone, 2,3-dimethyl-1-phenyl-5-pyrazolone, 2,3-dimethyl-4-dimethylamino-1-phenyl-5-pyrazolone, and benzopyrazole; imidazole based compounds such as imidazole, methylimidazole, 2,4,5-triphenylimidazole, 4-(2-aminoethyl)imidazole, and 2-amino-3-(4-imidazolyl)propionic acid; imidazoline based compounds such as 2-imidazoline, 2,4,5-triphenyl-2-imidazoline, and 2-(1-naphthylmethyl)-2-imidazoline; imidazolidine based compounds such as imidazolidine, 2-imidazolidone, 2,4-imidazolidinedione, 1-methyl-2,4-imidazolidinedione, 5-methyl-2,4-imidazolidinedione, 5-hydroxy-2,4-imidazolidinedione-5-carboxylic acid, 5-ureide-2,4-imidazolidinedione, 2-imino-1-methyl-4-imidazolidone, and 2-thioxo-4-imidazolidone; benzoimidazole based compounds such as benzoimidazole, 2 phenylbenzoimidazole, and 2-benzoimidazolinone; diazine based compounds such as 1,2-diazine, 1,3-diazine, 1,4-diazine, and 2,5-dimethylpyrazine; hydropyrimidine based compounds such as 2,4(1H, 3H)pyrimidinedione, 5-methyluracil, 5-ethyl-5-phenyl-4,6-perhydropyrimidinedione, 2-thioxo-4(1H, 3H)-pyrimidinone, 4-imino-2(1H, 3H)-pyrimidine, and 2,4,6(1H, 3H, 5H)-pyrimidinetrione; benzodiazine based compounds such as cinnoline, phthalazine, quinazoline, quinoxaline, and luminol; dibenzodiazine based compounds such as benzoshinorine, phenazine, and 5,10-dihydrophenazine; triazole based compounds such as 1H-1,2,3-triazole, 1H-1,2,4-triazole, and 4-amino-1,2,4-triazole; benzotriazole based compounds such as benzotriazole, and 5-methylbenzotriazole; triazine based compounds such as 1,3,5-triazine, 1,3,5-triazine-2,4,6-triol, 2,4,6-trimethoxy-1,3,5-triazine, 1,3,5-triazine-2,4,6-trithiol, 1,3,5-triazine-2,4,6-triamine, and 4,6-diamino-1,3,5-triazine-2-ol, and the like, but not limited thereto.

Among these, in light of ease in handling, ready availability and the like, a monomer of an imidazole based compound is preferably used, and particularly imidazole is preferably used.

The amount of the heterocyclic compound having two or more nitrogen atoms in at least the identical ring blended is preferably about 1 to 15% by mass, and more preferably about 2 to 10% by mass based on the mass of the water soluble resin. When the amount is less than 1% by mass, desired effects are hardly achieved, while desired effects are also hardly achieved when the amount is beyond 15% by mass, and further risk of generation of defects is increased.

### Water Soluble Amine Compound

A water soluble amine compound may be blended into the material for forming a coat film. Use of such a water soluble amine compound enables the prevention of the generation of impurities, and adjustment of the pH, and the like.

Examples of the water soluble amine compound include amines having a pKa (acid dissociation constant) in an aqueous solution at 25° C. of 7.5 to 13. Specific examples include alkanolamines such as monoethanolamine, diethanolamine, triethanolamine, 2-(2-aminoethoxy)ethanol, N,N-dimethyl ethanolamine, N,N-diethyl ethanolamine, N,N-dibutylethanolamine, N-methylethanolamine, N-ethylethanolamine, N-butylethanolamine, N-methyldiethanolamine, monoisopropanolamine, diisopropanolamine, and triisopropanolamine; polyalkylenepolyamines such as diethylene triamine, triethylene tetramine, propylenediamine, N,N-diethylethylene diamine, 1,4-butanediamine, N-ethyl-ethylene diamine, 1,2-propane diamine, 1,3-propane diamine, and 1,6-hexanediamine; aliphatic amines such as 2-ethyl-hexylamine, dioctylamine, tributylamine, tripropylamine, triallylamine, heptylamine, and cyclohexylamine; aromatic amines such as benzylamine, and diphenylamine; cyclic amines such as piperazine, N-methyl-piperazine, and hydroxyethylpiperazine, and the like. Among these, amines having a boiling point of no less than 140° C. (760 mmHg) are preferred, and for example, monoethanolamine, triethanolamine or the like may be preferably used.

The amount of the water soluble amine compound included is preferably about 0.1 to 30% by mass, and more preferably about 2 to 15% by mass of the solid content of the material for forming a coat film. When the amount is less than 0.1% by mass, time dependent deterioration of the liquid may result. In contrast, when the amount exceeds 30% by mass, impairment of the configuration of the resist pattern may result.

### Non-Amine Based Water Soluble Organic Solvent

A nonamine based water soluble organic solvent may be blended into the material for forming a coat film. Use of such a nonamine based water soluble organic solvent enables generation of the defect to be suppressed.

Such non-amine water-soluble organic solvents may be any solvent so long as it is a water miscible non-amine organic solvent, for example, sulfoxides such as dimethylsulfoxide and the like; sulfones such as dimethylsulfone, diethylsulfone, bis(2-hydroxyethyl)sulfone, tetramethylenesulfone, and the like; amides such as N,N-dimethylformamide, N-methylformamide, N,N-dimethylacetamide, N-methylacetamide, N,N-diethylacetamide, and the like; lactams such as N-methyl-2-pyrrolidone, N-ethyl-2-pyrrolidone, N-propyl-2-pyrrolidone, N-hydroxymethyl-2-pyrrolidone, N-hydroxyethyl-2-pyrrolidone, and the like; imidazolidinones such as 1,3-dimethyl-2-imidazolidinone, 1,3-diethyl-2-imidazolidinone, 1,3-diisopropyl-2-imidazolidinone, and the like; polyhydric alcohols such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether, diethylene glycol monobutyl ether, propylene glycol, propylene glycol monomethyl ether, glycerin, 1,2-butylene glycol, 1,3-butylene glycol, and 2,3-butylene glycol, and derivatives thereof. Among these, in light of suppression of the generation of the defect, and the like, polyhydric alcohols and derivatives thereof may be preferably used, and particularly glycerin is preferably used. The nonamine based water soluble organic solvent may be used alone, or two or more of them may be used.

The amount of the nonamine based water soluble organic solvent blended is preferably about 0.1 to 30% by mass, and more preferably about 0.5 to 15% by mass based on the water soluble resin. When the amount is less than 0.1% by mass, the effect of decreasing the defect is likely to deteriorate. In contrast, an amount exceeding 30% by mass is not preferred since a mixing layer with the resin pattern is likely to be formed.

### EXAMPLES

Hereinafter, the present invention is explained in more detail by way of Examples, but the present invention is not any how limited to these Examples.

### Example 1

A resist composition “TARF-P7152” (manufactured by Tokyo Ohka Kogyo Co., Ltd.) was applied by spin coating on an 8-inch silicon substrate, and subjected to a prebaking treatment (PAB) under a condition of 140° C. for 60 sec, whereby a photosensitive resin layer having a film thickness of 243 nm was formed. Next, this photosensitive resin layer was selectively exposed using an ArF excimer laser exposure device NSR-S302 (manufactured by Nikon Corporation, NA=0.68., σ=0.75) through a mask with a hole diameter of 1,200 nm, and a pitch of 2,400 nm. Subsequently, a baking treatment (PEB) was carried out under a condition of 140° C. for 60 sec, followed by development using a 2.38% by mass aqueous tetramethylammonium hydroxide solution for 30 sec, and washing with deionized water for 20 sec. As a result, a resin pattern of the photosensitive resin layer including hole patterns having a hole diameter of 300 nm arranged at regular intervals (hereinafter, referred to as pattern (1)) was formed.

Separately, an aqueous solution including polyvinylpyrrolidone “PVPK30” (manufactured by BASF Ltd.) as a water soluble resin, a urea based crosslinking agent “N-8314” (manufactured by SANWA Chemical Co., Ltd) as a water soluble crosslinking agent in an amount of 2.5% by mass based on the water soluble resin, and 500 ppm of dimethyllaurylamine oxide as a surfactant based on the total amount (total solid content=10% by mass) was prepared as a material for forming a coat film.

This material for forming a coat film was applied uniformly on the pattern (1) by spin coating, and thereafter subjected to a baking treatment under a condition of 130° C. for 60 sec, followed by washing with deionized water for 60 sec. As a result, a coat pattern having the surface of the pattern (1) covered by a uniform coat film (water soluble resin film) was obtained.

Subsequently, a resist composition “TARF-P6111” (manufactured by Tokyo Ohka Kogyo Co., Ltd.) was applied on the substrate having the coat pattern formed thereof under the conditions identical to those described above, and subjected to a prebaking treatment, whereby a photosensitive resin layer was formed. After the entire face of the photosensitive resin layer was exposed without a mask, it was washed with an aqueous 2.38% by mass tetramethylammonium hydroxide solution for 60 sec. As a result, a resin pattern (hereinafter, referred to as pattern (2)) having the surface of the coat pattern covered by a uniform resin film was obtained. This pattern (2) had a hole diameter of 280 nm, and also had a favorable pattern configuration.

### Example 2

A pattern (2) was formed in a completely similar manner to Example 1 except that the material for forming a coat film used in Example 1 was changed to an aqueous solution including polyvinylpyrrolidone “PVPVA64W” (manufactured by BASF Ltd.) as a water soluble resin, a urea based crosslinking agent “N-8314” (manufactured by SANWA Chemical Co., Ltd) as a water soluble crosslinking agent in an amount of 10% by mass based on the water soluble resin, and 500 ppm of dimethyllaurylamine oxide as a surfactant based on the total amount (total solid content=10% by mass). This pattern (2) had a hole diameter of 250 nm, and also had a favorable pattern configuration.

### Comparative Example 1

On a pattern (1) formed by a similar procedure to that in Example 1 was applied a resist composition “TARF-P6111” (manufactured by Tokyo Ohka Kogyo Co., Ltd.) without forming a coat film (water soluble resin film). As a result, the pattern (1) completely disappeared from on the substrate.

1. A method for forming a fine pattern, comprising:
forming a first resin pattern by applying a photosensitive resin composition on a support, followed by selectively exposing, and then developing;
forming a coat pattern by forming a coat film constituted with a water soluble resin film on the surface of the first resin pattern; and
forming a second resin pattern constituted with a resin film formed on the surface of the coat pattern, by applying a resin composition containing a photoacid generator on the support having the coat pattern formed thereon, followed by exposing the entire face, and then washing with a solvent.

2. The method for forming a fine pattern according to claim 1, wherein the coat film is formed using a material for forming a coat film, and wherein the material is constituted with an aqueous solution containing a water soluble resin and a water soluble crosslinking agent.

3. The method for forming a fine pattern according to claim 2, wherein the water soluble resin is at least one of an acrylic based resin, a vinyl based resin, a cellulose based resin, and an amide based resin.

4. The method for forming a fine pattern according to claim 2, wherein the water soluble resin is at least one of polyvinylpyrrolidone and polyvinyl alcohol.

5. The method for forming a fine pattern according to claim 2, wherein the water soluble crosslinking agent is at least one of a triazine based derivative, a glycoluril based derivative, and a urea based derivative.

6. (canceled)
